(19) United States
(12) Patent Application Publication
(10) Pub. No.: US 2011/0288797 A1
(43) Pub. Date: Nov. 24, 2011

(54) METHOD FOR DETERMINING THE CHARGE STATE OF A SECONDARY INTERCALATION CELL OF A RECHARGEABLE BATTERY

(76) Inventor: Alexander Schmidt, Donaueschingen (DE)

(21) Appl. No.: 13/132,861

(22) PCT Filed: Nov. 24, 2009
(86) PCT No.: PCT/EP2009/065685

§ 371 Date: Aug. 11, 2011

(30) Foreign Application Priority Data
Dec. 4, 2008 (DE) 10 2008 044 353.0
Jan. 11, 2009 (DE) 10 2009 000 782.2

(51) Int. Cl. G01R 31/36; G06F 19/00

(52) U.S. Cl. 702/63

(57) ABSTRACT

A method is described for determining the charge state of a secondary intercalation cell having an anode, a cathode, a separator, and an electrolyte phase, which saturates the anode, the cathode, and the separator, in which the charge state is back-calculated on the basis of measured variables, which are measured on the intercalation cell, with the aid of an electrochemical simulation model. In the fundamental simulation model, physical-chemical properties in the anode and the cathode are each considered in simplified form as being homogeneously distributed in the anode and in the cathode and Butler-Volmer reaction kinetics are calculated in each case for the anode and for the cathode. The Butler-Volmer reaction kinetics are expanded on the anode side by a potential component (Φ₂) in the electrolyte phase of the anode.

### FIELD OF THE INVENTION

The present invention relates to a method for determining the charge state of a secondary intercalation cell of a rechargeable battery, in particular for a motor vehicle.

### BACKGROUND INFORMATION

Secondary or dual electrochemical cells, commonly referred to as storage batteries, differ from primary electrochemical cells through their rechargeability.

In many technical applications it is desirable and even necessary to obtain information about the charge or discharge state of a secondary cell in particular, on the basis of variables which are measurable from outside the cell.

Model-based approaches are typically used for the charge state determination and prediction of secondary cells. These approaches include so-called equivalent circuit diagram models, which are to approximate the electrical behavior of a cell or battery using linear-passive elements, for example, using R, L, C elements. In general, however, the charge state, which is also referred to as the state of charge (SOC), is not directly measurable.

According to the related art, the SOC is typically ascertained as a function of the open-circuit voltage, i.e., the cell or battery open-circuit voltage, and/or from a current integration and/or from a combination which takes into consideration various state variables, for example, the last ascertained SOC, the cell or battery temperature, the cell or battery open-circuit voltage, the strength of the cell or battery current, and the like.

A method for determining the charge state of a storage battery provided as a vehicle starter battery in a vehicle having a starter is discussed in DE 198 31 723 A1. The voltage drop of the battery voltage is detected during the operation of the starter and subsequently assigned to a charge state value.

A method for determining the charge state of a storage battery is discussed in DE 199 13 627 A1, which provides, in the case of a storage battery which is charged using a variable power source, in that the power generated by the variable power source is converted into defined current pulses and pulse pauses and supplied in this form to the storage battery, that the charge state is determined in that the voltage curve in the storage battery is measured and analyzed as a reaction to the current pulses.

A method for determining the charge state of a storage battery provided as a vehicle starter battery is also discussed in DE 198 31 723 A1, this vehicle starter battery being used within the scope of a vehicle operation without idle times. In the case of the existence of an operating range which may relate to the discharge operating range of the battery, the charge state is calculated on the basis of a model calculation, in which a measured battery voltage and a calculated battery voltage are aligned via feedback. The fundamental model calculation emanates from a nearly linear relationship between charge Q of the battery and open-circuit voltage U_{R} of the battery, which is provided by capacitance C of the battery. The dynamic response of the acid density equalization between the plate pores and the free acid volume of the vehicle starter battery, which is implemented as a classic lead storage battery, is simulated in the model calculation using a concentration overvoltage U_{K} over a capacitance C_{K}, which is situated in series to capacitance C of the battery, and a resistance R_{K}, which is in parallel to capacitance C_{K}. Furthermore, the model calculation includes an internal resistance R_{I} of the battery, which is situated in series to capacitance C of the battery. At first, a battery voltage U_{batt} and a battery current I_{batt} are measured. Battery current I_{batt} is input directly into the model calculation. Measured battery voltage U_{batt} is aligned with an estimated battery voltage U_{batt}′ and also input into the model calculation, in order to calculate an open-circuit voltage value U_{R}. To estimate open-circuit voltage U_{R}, concentration overvoltage U_{K}, and internal resistance R_{I}, an observer in the form of a Kalman filter, for example, is used. The model calculation is aligned in the discharge operating range by feedback of the error between measured battery voltage U_{batt} and estimated battery voltage U_{batt}′. In the remaining operating ranges, the feedback of the error of the model calculation is interrupted and the open-circuit voltage is calculated from the current integral and the last open-circuit voltage estimated during the last discharge operating range. The SOC is determined according to an equation of the form

$$SOC = f ( {U}_{R} ) = \frac{{U}_{R} - {U}_{R , min}}{{U}_{R , max} - {U}_{R , min}}$$

U_{R,min} and U_{R,max} designating the minimum and maximum open-circuit voltages, respectively, at the values specified by the battery manufacturer of the acid density for a discharged or fully-charged battery.

A further method for determining the charge state of a vehicle battery is known from DE 101 39 049 A1. For this purpose, a charge state determination operation is initially activated, subsequently a defined load current is set by activating at least one electric machine of the vehicle, and a voltage characteristic is derived from a measured onboard electrical system voltage. In addition, information about the battery temperature of the vehicle is provided and finally the charge state of the vehicle battery is ascertained using the voltage characteristic, the battery temperature, and a stored characteristic map.

A method for determining the charge state of a storage battery is also discussed in DE 103 01 823 A1. In order to determine the charge which may be withdrawn from a lead storage battery up to a predefined discharge conclusion, a model calculation is used, which mathematically represents the electrical properties of the lead storage battery. With the aid of the model calculation, the charge which may be withdrawn at a predefined discharge current is calculated, state variables and/or parameters for the model calculation being ascertained from the following instantaneous operating variables: battery voltage, battery current, and battery temperature of the lead storage battery.

The above-mentioned methods have the disadvantage that their simple structure for determining the SOC using only a few parameters is gained by complex dependencies of the parameters of SOC, cell temperature, and amperage. As a result, the model calculations are only applicable in a narrow operating range. Accordingly, to cover all possible operating states, multiple model calculations or parameter-variant model calculations must be applied. This may result in instability of the algorithm on which the model calculations are based, if the parameters change strongly.

Furthermore, a metrological implementation of the current integration is generally heavily subject to errors, which may result in strong deviations in the SOC prediction or determination. Furthermore, the dependence of the battery capacitance on the withdrawn power is not considered.

In addition, the storage batteries in which the above-mentioned methods are provided and also are substantially suitable for predicting the particular SOC have heretofore been lead storage batteries which are used as vehicle starter batteries, for example. These do meet requirements as are needed for use in particular for short-term applications in motor vehicles, e.g., high discharge currents, simple construction, and cost-effective manufacture; however, they have significant disadvantages with respect to their energy density.

So-called intercalation cells, in which the electromotor force is not generated by a chemical reaction of the materials of the electrodes, as in lead storage batteries, for example, but rather by a displacement of ions, have substantially higher energy densities.

In general, in the case of intercalation, molecules, ions, or atoms are intercalated in compounds, without the compounds substantially changing their structure during the intercalation process. In particular in inorganic chemistry, intercalation refers to the intercalation of atoms, ions, or small molecules between the crystal lattice planes of layered crystals.

In an intercalation cell, positively charged ions travel during the charge process from the cathode through an electrolyte between the crystal lattice planes of the anode, while the electrons deliver the charge current via the external power circuit. The ions form so-called intercalation complexes with the material of the anode. During discharge, the ions travel through the electrolyte back into the metal oxide of the cathode and the electrons may flow via the external power circuit to the cathode.

An example of an intercalation cell which is known per se is a lithium-ion storage battery and its refinements, for example, a lithium-polymer storage battery, a lithium-titanate storage battery, a supercharged ion battery (SCIB), a lithium-manganese storage battery, or a lithium-iron-phosphate storage battery.

In an intercalation cell, the determination of the charge state or the SOC proves to be substantially more difficult than in the case of a typical lead storage battery, for example, since the intercalation forms a spatial distribution which significantly influences a fundamental simulation model.

A schematic construction of a known lithium-ion intercalation cell 01 is shown in FIG. 1. Lithium-ion intercalation cell 01, which is also referred to simply as cell 01, essentially includes a porous cathode 11 or positive electrode 11, which is formed by active particles 02, a porous anode 12 or negative electrode 12, which is formed by active particles 04, and a separator 13 situated between electrodes 11, 12. Remaining cavities between particles 02, 04 of electrodes 11, 12 are filled using an electrolyte 10 and binder and filler material 02a, 04a.

An alternative approach for determining the SOC, which is also usable for intercalation cells, is modeling with the aid of the fundamental physical and/or chemical effects in the cell. Reference is made in this context to an electrochemical simulation model.

Electrochemical simulation models are known from M. DOYLE, T. FULLER, J. NEWMAN “Modeling of galvanostatic charge and discharge of the lithium/polymer/insertion cell,” Journal of the Electrochemical Society 140 (1993), pp. 1526-1533, and T. FULLER, M. DOYLE, J. NEWMAN, “Simulation and optimization of the dual lithium ion insertion cell,” Journal of the Electrochemical Society 141 (1994), pp. 1-10, which simulate the physical and chemical effects in a dual or secondary lithium ion intercalation cell 01, which is schematically shown in its construction in FIG. 1. Lithium-ion intercalation cell 01, which is also referred to simply as cell 01, essentially includes a porous cathode 11 or positive electrode 11, which is formed by active particles 02, a porous anode 12 or negative electrode 12, which is formed by active particles 04, and a separator 13 situated between electrodes 11, 12. Remaining cavities between particles 02, 04 of electrodes 11, 12 are filled using an electrolyte 10, which is also referred to as an electrolyte phase, and binder and filler material 02a, 04a.

These electrochemical simulation models allow the calculation or consideration of the following physical and chemical effects:
diffusion of lithium ions Li+ in electrodes 11, 12 or between particles 02, 04 thereof,
diffusion of lithium ions Li+ in the electrolyte phase,
Ohm's law for the potential in the electrolyte phase,
Ohm's law for the potential in active electrode material 02, 04 of electrodes 11, 12,
current balance in electrolyte phase 10, and
Butler-Volmer reaction kinetics for the charge passage through the interface between active particles and the electrolyte.

These simulation models belong to the class of the so-called distributed systems, since they consider a local variation of state variables over the cell cross-section, which is schematically shown in FIG. 1 by a linear scale 09, or since the local variation of state variables is also calculated over the cell cross-section. Each division of scale 09 symbolizes a point of discretization for the partial differential equations in the distributed system. This results in a high model order, connected with a corresponding computing effort. In the original Fortran code (J. NEWMAN, “Fortran programs for the simulation of electrochemical systems,” http://www.cchem.berkeley.edu/jsngrp/fortran.html (1998)), 200 spatial points of discretization were used. In consideration of six physical equations, 1200 equations thus result, which must be solved for every time step.

From the control-technological point of view, in the simulation models, the introduced or required current, which is schematically shown by arrows 06 or 07 in FIG. 1, is the input variable and the cell voltage, which is schematically shown by a voltmeter 08, is the observable output variable. The cell voltage results from the potential of active electrode material 02 at right edge 03 of cell 01 minus the potential of active electrode material 04 at left edge 05 of cell 01. The SOC physically results from the diffusion-based concentration of lithium ions Li+ in the active particles of electrodes 02, 04 or in active electrode material 02, 04 and is back-calculated from cell voltage 08.

The advantages of these electrochemical simulation models, which form distributed systems, are accurate reproduction of the cell behavior, consideration of a power-dependent capacitance, and a physical calculation of the SOC from the lithium ion concentration in the active electrode material. The disadvantages of these electrochemical simulation models, which form distributed systems, are a high number of parameters (more than 50 parameters), an enormously high computing effort, which conflicts with real-time capability, and disadvantageous numerical conditioning. In addition, the procedures on which the distributed electrochemical simulation models are based are not observable in practical applications, where only current, voltage, and temperature are measurable.

A system which is also referred to as a single-particle model is known from S. SANTHANAGOPALAN, R. E. WHITE “Online estimation of the state of charge of a lithium ion cell,” Journal of Power Sources 161 (2006), pp. 1346-1355, which, in contrast to the above-described distributed systems, averages the physical-chemical properties via the electrodes and neglects the influences of the processes in the electrolyte phase and in the separator. The averaging via the electrodes is performed in that the physical-chemical properties, which are observed in the distributed system in multiple spatial points of discretization, are each averaged via the anode and the cathode. The influences of the processes in the electrolyte phase and in the separator are neglected in that the influence of the lithium ions in the electrolyte phase is neglected.

More precisely, in the single-particle model, each porous electrode is considered in simplified form as a single spherical particle immersed in the electrolyte phase, whose surface is scaled to the surface of the particular porous electrode. In addition, in the single-particle model, concentration and potential changes in the electrolyte phase are not considered. In addition, all parameters are kept constant and thermal influences are neglected. The lithium concentration in the anode and in the cathode is determined on the basis of the lithium concentration on the surface of the particular spherical particle and the average concentration within the spherical particle. The Butler-Volmer reaction kinetics are applied in each case for the surfaces of the spherical particles forming the anode and the cathode.

Emanating from a distributed system, a simulation model which is thus formed is therefore essentially reduced to the following electrochemical effects:
Butler-Volmer reaction kinetics for the charge passage through the interface between the two spherical particles forming the electrodes and the electrolyte phase surrounding them and
diffusion of lithium ions in the electrodes, which are each formed by a spherical particle or assumed as such.

The SOC physically results in this case from the concentration of the lithium ions in the two electrodes, which are considered as being homogeneous and may also be referred to as electrode particles.

The single-particle model is a so-called lumped parameter system, whose core property is to average spatially distributed system states. Advantages resulting therefrom are that the spatial discretization is thus dispensed with and only eight equations still remain to be solved per time step, whereby the single-particle model is real-time capable, i.e., it is fundamentally capable of predicting the SOC of an intercalation cell which is in operation or use.

A disadvantage of the single-particle model is that the output voltage coincides only up to a charge or discharge current of up to ±3 C with the simulation models forming the distributed systems. At higher currents, the single-particle model deviates significantly more than 10 mV. A significant error of the SOC of greater than 5% is connected thereto.

### SUMMARY OF THE INVENTION

The exemplary embodiments and/or exemplary methods of the present invention emanates from a method described at the outset for determining the charge state or SOC of a secondary intercalation cell of a rechargeable battery having an anode, a cathode, a separator, and an electrolyte phase, which saturates the anode, the cathode, and the separator, the charge state being back-calculated on the basis of measured variables, which are measured on the intercalation cell, with the aid of an electrochemical simulation model, in which simulation model physical-chemical properties, such as a concentration of the atoms and/or molecules and/or ions, which are intercalated in the anode and the cathode during the intercalation, and are considered in simplified form as being homogeneously distributed in each case in the anode and in the cathode, and in which simulation model Butler-Volmer reaction kinetics are calculated in each case for the anode and for the cathode. It is provided according to the exemplary embodiments and/or exemplary methods of the present invention that the Butler-Volmer reaction kinetics are expanded on the anode side by a potential component in the electrolyte phase of the anode.

Advantages of the exemplary embodiments and/or exemplary methods of the present invention in relation to the related art result, among other things, in that a high precision is achieved, as in a distributed system, with a simultaneously simple and therefore real-time-capable algorithm having only a few parameters, as in a lumped-parameter system.

For the anode-side expansion of the Butler-Volmer reaction kinetics by a potential component in the electrolyte phase of the anode, the potential component in the electrolyte phase of the anode may be estimated in that the concentration of the atoms and/or molecules and/or ions which are intercalated in the anode during the intercalation is transferred to the electrolyte phase and thus the potential component is approximately calculated.

According to an alternative embodiment of the present invention, for the anode-side expansion of the Butler-Volmer reaction kinetics, the potential component in the electrolyte phase of the anode may be estimated on the basis of the charge or discharge current of the cell, the mean conductivity of the electrolyte phase, and the thickness of an anode-separator-cathode sandwich, which is formed by the layers of the anode, the separator, and the cathode.

The exemplary embodiments and/or exemplary methods of the present invention thus allows a model-based prediction of the charge state of a secondary intercalation cell for all operating points within the specification of cell temperature, cell voltage, and charge or discharge current of the cell by measuring the load current and terminal voltage of the cell.

Overpotential η_{s,a} of the Butler-Volmer reaction kinetics of the anode, which are expanded by the potential component in the electrolyte phase of the anode, may be calculated according to

η_{s,a}=Φ_{s,a}−Uₐ(c_{s,a})−Φ₂(k,I,L)−Φ_{SEI}

where Φ_{s,a} is the voltage drop in the solid phase at a charge or discharge current I of the cell, Uₐ(c_{s,a}) is the open-circuit voltage of the anode as a function of concentration c_{s,a} of the atoms and/or molecules and/or ions which are intercalated in the active particles of the anode during the intercalation, Φ_{SEI} is the potential drop due to the film resistance on the surface of the anode, and Φ₂(k,I,L) is the potential component corresponding to a voltage drop in the electrolyte phase of the anode as a function of mean conductivity k of the electrolyte phase, charge or discharge current I of the cell, and thickness L of the anode-separator-cathode sandwich.

An advantageous embodiment of the method according to the present invention provides that potential component Φ₂(k,I,L) in the electrolyte phase of the anode is calculated according to Φ₂=k⁻¹·L·I(t), where k is the mean conductivity of the electrolyte phase, L is the thickness of the anode-separator-cathode sandwich, and l(t) is the charge or discharge current of the cell as a function of time t, mean conductivity k of the electrolyte phase being estimated on the basis of the charge or discharge current of the cell l(t).

Alternatively to the above-described embodiment variant, it is conceivable that potential component Φ₂(k,I,L) in the electrolyte phase of the anode is calculated according to Φ₂=k⁻¹·L·I(t), where k is the mean conductivity of the electrolyte phase, L is the thickness of the anode-separator-cathode sandwich, and l(t) is the charge or discharge current of the cell as a function of time t, mean conductivity k of the electrolyte phase being estimated on the basis of a mean value of the charge or discharge current of the cell l(t).

Mean conductivity k of the electrolyte phase may be weighted using an empirical weighting w. The mean conductivity of the electrolyte phase thus results, together with empirical weighting w, in a lumping parameter.

The charge state may be back-calculated with the aid of the simulation model on the basis of the following measured variables: cell temperature, cell voltage, and charge or discharge current of the cell.

A particularly advantageous embodiment of the present invention provides that the anode and the cathode, in the case of the calculation of the Butler-Volmer reaction kinetics for the anode and for the cathode, are each considered in simplified form as a spherical particle having a spherical surface corresponding to the surface of the anode or the cathode of a real secondary intercalation cell, within which the physical-chemical properties are each considered to be homogeneously distributed.

The physical-chemical properties in the anode and in the cathode may be calculated on the basis of the particular last calculated physical-chemical properties in the anode and in the cathode and on the basis of the physical-chemical properties on the surface of the anode and the cathode.

Another particularly advantageous embodiment of the present invention provides that the particular physical-chemical properties which are considered to be homogeneously distributed in the anode and in the cathode at least include the concentration of the atoms and/or molecules and/or ions which are intercalated in each case in the anode and in the cathode during the intercalation.

The secondary intercalation cell particularly may be a lithium-ion intercalation cell.

Exemplary embodiments of the present invention are explained on the basis of the drawings.

### BRIEF DESCRIPTION OF THE DRAWINGS

FIG. 1 shows a schematic construction of a secondary or dual intercalation cell.

FIG. 2 shows a schematic view of an application of the method according to the present invention.

FIG. 3 shows a schematic view of an electrochemical simulation model on which the method according to the present invention is based.

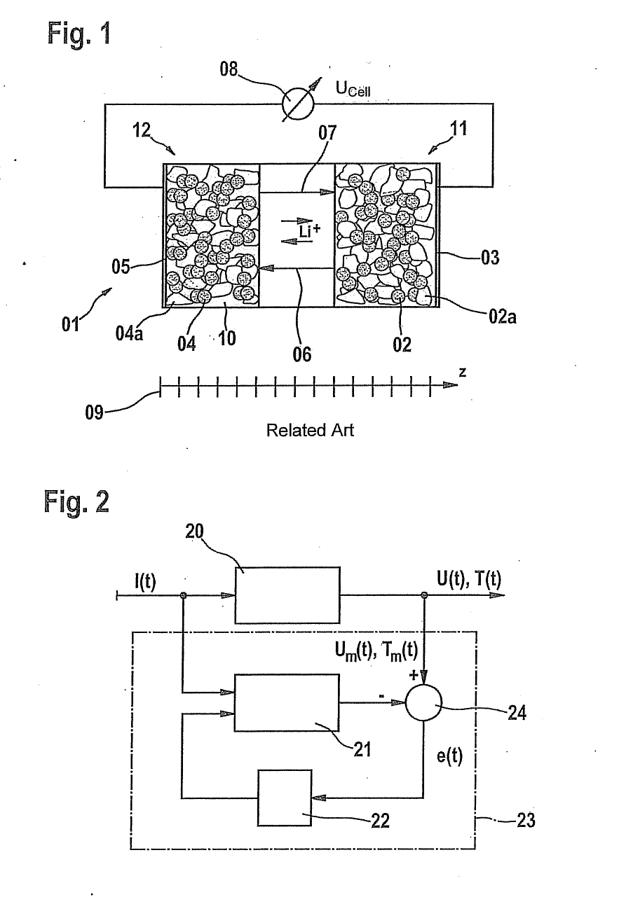

### DETAILED DESCRIPTION

A method for determining the charge state or SOC of a secondary intercalation cell 20, which may be implemented as a lithium-ion storage battery, may be used, as schematically shown in FIG. 2, in that the SOC of intercalation cell 20 is back-calculated on the basis of measured variables, which are measured on intercalation cell 20 at point in time t, cell temperature T(t), cell voltage U(t), and charge or discharge current of the cell l(t), with the aid of an electrochemical simulation model 21. The measured charge or discharge current of the cell l(t) may be used as an input variable of simulation model 21, the output variables cell temperature Tₘ(t) and cell voltage Uₘ(t) of the simulation model being compared to the measured variables cell temperature T(t) and cell voltage U(t) of intercalation cell 20.

A feedback amplification 22 of an observation error e(t) resulting from the comparison may be determined according to Luenberger or Kalman. The SOC is reconstructed from the measured variables and charge or discharge current of the cell l(t), cell temperature T(t), and cell voltage U(t). A starting SOC may be ascertained by a state observer 23, such as a Kalman filter.

In order to obtain a prediction of the SOC in an application shown in FIG. 2, which may be at the same time or close to point in time t, simulation model 21 must be based on an algorithm which manages without computing-intensive parameter characteristic maps.

For example, for a vehicle application, e.g., in a motor vehicle equipped with a secondary intercalation cell, e.g., an electric or hybrid vehicle, a simulation model, which is provided for a method for determining the SOC of the secondary intercalation cell and is formed by such an algorithm, must simulate the power-dependent and temperature-dependent capacitance of the intercalation cell, must have a quality comparable to a distributed system, for example, to a simulation model forming a distributed system known from M. DOYLE, T. FULLER, J. NEWMAN “Modeling of galvanostatic charge and discharge of the lithium/polymer/insertion cell,” Journal of the Electrochemical Society 140 (1993), pp. 1526-1533, and from T. FULLER, M. DOYLE, J. NEWMAN, “Simulation and optimization of the dual lithium ion insertion cell,” Journal of the Electrochemical Society 141 (1994), pp. 1-10, must be observable as defined in control technology, and must include at most approximately ten parameters and system states, in order to be real-time capable.

This is ensured by a method according to the present invention for determining the SOC of a secondary intercalation cell having an anode, a cathode, a separator, and an electrolyte phase which saturates the anode, the cathode, and the separator, in which the charge state is back-calculated on the basis of measured variables, which are measured on the intercalation cell, with the aid of an electrochemical simulation model 21, in which simulation model 21 physical-chemical properties, for example, a diffusion-based concentration of the atoms and/or molecules and/or ions which are intercalated in the anode and in the cathode, during the intercalation are each considered in simplified form as being homogeneously distributed in the anode and in the cathode, and in which simulation model 21 Butler-Volmer reaction kinetics are calculated in each case for the anode and for the cathode.

The measure of a homogeneously distributed consideration ensures that simulation model 21 only includes a few parameters, so that the fundamental algorithm is real-time capable. In order to obtain the precision of a distributed system without having to accept its disadvantages, such as a lack of real-time capability, it is additionally provided that the Butler-Volmer reaction kinetics are expanded on the anode side by a potential component in the electrolyte phase of the anode.

Fundamental simulation model 21 of the method according to the present invention may be based on the real-time-capable single-particle model known from S. SANTHANAGOPALAN, R. E. WHITE “Online estimation of the state of charge of a lithium ion cell,” Journal of Power Sources 161 (2006), pp. 1346-1355, in which the Butler-Volmer reaction kinetics are expanded according to the present invention on the anode side by a potential component in the electrolyte phase of the anode.

This expansion may be performed by an estimation of potential component Φ₂ in the electrolyte phase of the anode on the basis of the charge or discharge current of the cell l, mean conductivity k of the electrolyte phase, and thickness L of the anode-separator-cathode sandwich.

Therefore, in contrast to S. SANTHANAGOPALAN, R. E. WHITE “Online estimation of the state of charge of a lithium ion cell,” Journal of Power Sources 161 (2006), pp. 1346-1355, both in the case of charge and also discharge currents >3C, the precision of the distributed systems known from, for example, M. DOYLE, T. FULLER, J. NEWMAN “Modeling of galvanostatic charge and discharge of the lithium/polymer/insertion cell,” Journal of the Electrochemical Society 140 (1993), pp. 1526-1533, and from T. FULLER, M. DOYLE, J. NEWMAN, “Simulation and optimization of the dual lithium ion insertion cell,” Journal of the Electrochemical Society 141 (1994), pp. 1-10 is achieved. Computing time and number of parameters remain in contrast, at the level of a lumped-parameter system, for example, the single-particle model.

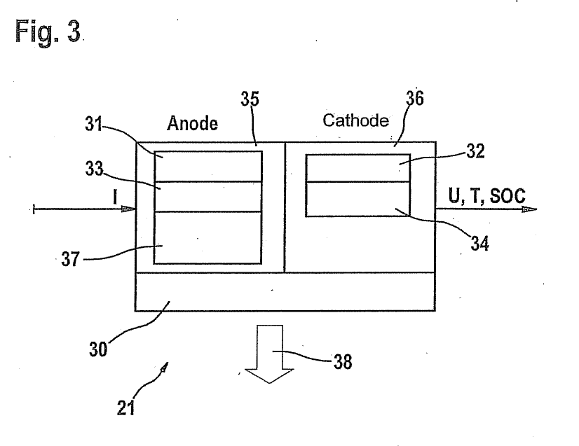

The essential components of an electrochemical simulation model 21 are shown in FIG. 3. It includes Butler-Volmer reaction kinetics 31 for anode 35, Butler-Volmer reaction kinetics 32 for cathode 36, a simplified calculation 33, which is considered to be distributed homogeneously in anode 35, of the concentration of the atoms and/or molecules and/or ions which are intercalated in anode 35 during the intercalation and a simplified calculation 34, which is considered to be distributed homogeneously in cathode 36, of the concentration of the atoms and/or molecules and/or ions which are intercalated in cathode 36 during the intercalation. Furthermore, a thermal current 30 from the resistive power, which is discharged by convection and/or radiation to the surroundings, may be taken into consideration. Butler-Volmer reaction kinetics 31 are expanded on the anode side by an estimation 37 of the potential component in the electrolyte phase of anode 35. Charge or discharge current I forms the input variable, cell voltage U and cell temperature T as well as the SOC form the output variables of simulation model 21.

The anode-side expansion of the Butler-Volmer reaction kinetics by a potential component Φ₂ in the electrolyte phase of the anode may be performed in such a way that overpotential η_{s,a} in the Butler-Volmer reaction kinetics of the anode or the negative electrode results as

η_{s,a}=Φ_{s,a}−Uₐ(c_{s,a})−Φ₂(k,I,L)−Φ_{SEI}

where Φ_{s,a} is the voltage drop in the solid phase, i.e., in the active particles of the anode, at a charge or discharge current I of the cell, Uₐ(c_{s,a}) is the open-circuit voltage of the anode as a function of concentration cₐ of the atoms and/or molecules and/or ions which are intercalated in the active particles of the anode during the intercalation, Φ_{SEI} is the potential drop due to the film resistance on the surface of the anode, and Φ₂(k,I,L) is the potential component corresponding to a voltage drop in the electrolyte phase of the anode as a function of mean conductivity k of the electrolyte phase, charge or discharge current I of the cell, and thickness L of the anode-separator-cathode sandwich.

The nearly stationary value at the left edge of the anode is estimated after a current jump according to the present invention. This is possible since potential component Φ₂ at the right edge of the cathode is equal to zero, whereby the reaction kinetics in the cathode are not influenced by potential component Φ₂.

Potential component Φ₂(k,I,L) in the electrolyte phase of the anode may be calculated according to Φ₂=w·k⁻¹·L·I(t), where k is the mean conductivity of the electrolyte phase, L is the thickness of the anode-separator-cathode sandwich, and l(t) is the charge or discharge current of cell l(t) as a function of time t, mean conductivity k of the electrolyte phase being estimated on the basis of the charge or discharge current of cell l(t) and may be weighted using an empirical weighting w. The mean conductivity of the electrolyte phase thus results in a lumping parameter together with empirical weighting w.

Weighting w may be selected as w=0.7, so that potential component Φ₂(k,I,L) in the electrolyte phase of the anode results as

Φ₂=0.7·k⁻¹·L·I(t).

Mean conductivity k of the electrolyte phase may be taken from the parameter set of a distributed model. Concentration c_{s,a} of atoms and/or molecules and/or ions which are intercalated in the active particles of the anode during the intercalation may be calculated via a fourth-order polynomial known from V. SUBRAMANIAN, V. DIWAKAR, D. TAPRIYAL “Efficient macro-micro scale coupled modeling of batteries,” Journal of the Electrochemical Society 152 (2005), A2002-A2008.

The term is fed in each case into the anode part of the Butler-Volmer reaction kinetics and replaces the numerical solution of two parallel differential equations, one differential equation for the diffusion of the atoms and/or molecules and/or ions which are intercalated in the anode during the intercalation, and one differential equation for the potential in the electrolyte, which is otherwise required for a determination of potential component Φ₂(k,I,L) in the electrolyte phase of the anode.

It is important to emphasize that the Butler-Volmer reaction kinetics may also be expanded on the cathode side by a potential component in the electrolyte phase of the cathode. However, the influence of the potential component in the electrolyte phase of the anode on the prediction of the SOC is substantially higher than the influence of the potential component in the electrolyte phase of the cathode, because of which the latter may remain unconsidered to simplify the algorithm.

It is also important to emphasize that the idea on which the present invention is based may also be expanded to other cell chemistries of comparable internal structure.

1-12. (canceled)

13. A method for determining a charge state of a secondary intercalation cell having an anode, a cathode, a separator, and an electrolyte phase which saturates the anode, the cathode, and the separator, the method comprising:
determining the charge state by back-calculating base on measured variables, which are measured on the intercalation cell, with an electrochemical simulation model, in which simulation model physical-chemical properties in the anode and the cathode are considered in simplified form as being homogeneously distributed in the anode and in the cathode in each case;
determining simulation model Butler-Volmer reaction kinetics in each case for the anode and the cathode; and
expanding the Butler-Volmer reaction kinetics on the anode side by a potential component in the an electrolyte phase of the anode.

14. The method of claim 13, wherein, for the anode-side expansion of the Butler-Volmer reaction kinetics by a potential component in the electrolyte phase of the anode, the potential component in the electrolyte phase of the anode is estimated in that the concentration of ions in the electrolyte phase is estimated and thus the potential component is approximately calculated.

15. The method of claim 13, wherein, for the anode-side expansion of the Butler-Volmer reaction kinetics, the potential component in the electrolyte phase of the anode is estimated based on the charge or discharge current of the cell, the mean conductivity of the electrolyte phase, and the thickness of an anode-separator-cathode sandwich.

16. The method of claim 15, wherein the overpotential η_{s,a} of the Butler-Volmer reaction kinetics of the anode, which are expanded by a potential component in the electrolyte phase of the anode, is calculated according to
η_{s,a}=Φ_{s,a}−Uₐ(c_{s,a})−Φ₂(k,I,L)−Φ_{SEI}
where Φ_{s,a} is the voltage drop in the solid phase at a charge or discharge current I of the cell, Uₐ(c_{s,a}) is the open-circuit voltage of the anode as a function of concentration c_{s,a} of atoms, molecules and/or ions which are intercalated in the active particles of the anode during the intercalation, Φ_{SEI} is the potential drop due to the film resistance on the surface of the anode, and Φ₂(k,I,L) is the potential component in the electrolyte phase of the anode as a function of mean conductivity k of the electrolyte phase, charge or discharge current I of the cell, and thickness L of the anode-separator-cathode sandwich.

17. The method of claim 16, wherein the potential component Φ₂(k,I,L) in the electrolyte phase of the anode is calculated according to Φ₂=k⁻¹·L·I(t), where k is the mean conductivity of the electrolyte phase, L is the thickness of the anode-separator-cathode sandwich, and l(t) is the charge or discharge current of the cell as a function of time t, the mean conductivity k of the electrolyte phase being estimated on the basis of the charge or discharge current of the cell l(t) and the terminal voltage.

18. The method of claim 16, wherein the potential component Φ₂(k,I,L) in the electrolyte phase of the anode is calculated according to Φ₂=k⁻¹·L·I(t), where k is the mean conductivity of the electrolyte phase, L is the thickness of the anode-separator-cathode sandwich, and l(t) is the charge or discharge current of the cell as a function of time t, the mean conductivity k of the electrolyte phase being estimated on the basis of the charge or discharge current of the cell l(t).

19. The method of claim 16, wherein the mean conductivity k of the electrolyte phase is weighted using a weighting w.

20. The method of claim 13, wherein the charge state is back-calculated on the basis of the measured variables of cell temperature, cell voltage, and charge current or discharge current of the cell.

21. The method of claim 13, wherein, during the calculation of the Butler-Volmer reaction kinetics, the anode and the cathode are each considered in simplified form as a spherical particle whose surface is scaled to the surface of the anode or the cathode of a real secondary intercalation cell, within each of which the physical-chemical properties are considered to be homogeneously distributed.

22. The method of claim 21, wherein the physical-chemical properties in the anode and in the cathode are calculated on the basis of the particular last calculated physical-chemical properties in the anode and in the cathode and on the basis of the physical-chemical properties on the surface of the active material of the anode and the cathode.

23. The method of claim 13, wherein the physical-chemical properties, which are considered to be homogeneously distributed in each case in the anode and in the cathode, at least include the concentration of the atoms and/or molecules and/or ions which are intercalated in each case in the anode and in the cathode during the intercalation.

24. The method of claim 13, wherein the secondary intercalation cell is a lithium-ion intercalation cell.
